(19) United States
(12) Patent Application Publication
(10) Pub. No.: US 2015/0349235 A1
(43) Pub. Date: Dec. 3, 2015

(54) WAVEFORM GENERATING APPARATUS, SIGNAL GENERATING CIRCUIT, PIEZOELECTRIC DRIVING APPARATUS AND METHOD, AND ELECTRONIC DEVICE USING THE SAME

(71) Applicant: SAMSUNG ELECTRO-MECHANICS CO., LTD., Suwon-si (KR)

(72) Inventor: Joo Yul KO, Suwon-si (KR)

(73) Assignee: SAMSUNG ELECTRO-MECHANICS CO., LTD., Suwon-si (KR)

(21) Appl. No.: 14/636,706

(22) Filed: Mar. 3, 2015

(30) Foreign Application Priority Data
Jun. 3, 2014 (KR) 10-2014-0067380
Jul. 30, 2014 (KR) 10-2014-0097648

(51) Int. Cl. H01L 41/04

(52) U.S. Cl. CPC H01L 41/042

(57) ABSTRACT

A piezoelectric driving apparatus may include a waveform synthesizing unit outputting a digital value, a digital-to-analog converting unit converting the digital value to an analog signal, and an output unit adding a direct current (DC) voltage to the analog signal to generate an asymmetrical driving signal.

### CROSS-REFERENCE TO RELATED APPLICATIONS

This application claims priority to and the benefit of Korean Patent Application Nos. 10-2014-0067380 filed on Jun. 3, 2014 and 10-2014-0097648 filed on Jul. 30, 2014 with the Korean Intellectual Property Office, the disclosures of which are incorporated herein by reference.

### BACKGROUND

The present disclosure relates to a waveform generating apparatus, a signal generating circuit, a piezoelectric driving apparatus, a piezoelectric driving method, and an electronic device using the same.

A multilayer piezoelectric element including a plurality of piezoelectric layers may have a limited operating voltage. In addition, due to the limitations of the operating voltage, output characteristics of the piezoelectric element may be decreased.

The related art may be understood with reference to Japanese Patent Laid-Open Publication No. 2005-237145 and Korean Patent Laid-Open Publication No. 2007-0042972.

### RELATED ART DOCUMENTS

(Patent Document 1) Japanese Patent Laid-Open Publication No. 2005-237145

(Patent Document 2) Korean Patent Laid-Open Publication No. 2007-0042972

### SUMMARY

An aspect of the present disclosure may provide a waveform generating apparatus, a signal generating circuit, a piezoelectric driving apparatus, a piezoelectric driving method, and an electronic device using the same, able to provide a relatively high output while protecting dielectric characteristics of a multilayer piezoelectric element.

According to an aspect of the present disclosure, a piezoelectric driving apparatus may generate a pair of output waveforms and shift the pair of output waveforms so as to generate an asymmetrical driving signal.

### BRIEF DESCRIPTION OF THE DRAWINGS

The above and other aspects, features and other advantages in the present disclosure will be more clearly understood from the following detailed description taken in conjunction with the accompanying drawings, in which:

FIG. 1 is a diagram of an electronic device according to an exemplary embodiment in the present disclosure;

FIG. 2 is a cross-sectional view of a multilayer piezoelectric element according to an exemplary embodiment in the present disclosure;

FIG. 3 is a graph illustrating an example of a pair of differential signals applied to both electrode terminals of the multilayer piezoelectric element, respectively;

FIG. 4 is a graph illustrating the differential signals of FIG. 3 as a single driving signal;

FIG. 5 is a graph illustrating an example of displacement depending on a voltage applied to a multilayer piezoelectric element;

FIG. 6 is a block diagram illustrating an example of a signal generating apparatus according to an exemplary embodiment in the present disclosure;

FIG. 7 is a block diagram illustrating an example of a piezoelectric driving apparatus according to an exemplary embodiment in the present disclosure;

FIG. 8 is a graph illustrating an example of signals respectively output from components of the piezoelectric driving apparatus of FIG. 7;

FIG. 9 is a graph illustrating an example of differential signals provided from the piezoelectric driving apparatus of FIG. 7;

FIG. 10 is a graph illustrating an example of an asymmetrical driving signal obtained from the differential signals of FIG. 9;

FIG. 11 is a block diagram illustrating an example of an output unit of FIG. 7;

FIG. 12 is a circuit diagram illustrating an example of an amplifier of FIG. 11;

FIG. 13 is a block diagram illustrating another example of the output unit of FIG. 7;

FIG. 14 is a circuit diagram illustrating an example of a voltage distributor of FIG. 13; and

FIG. 15 is a flowchart illustrating an example of a signal generating method.

### DETAILED DESCRIPTION

Hereinafter, embodiments in the present disclosure will be described in detail with reference to the accompanying drawings.

The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

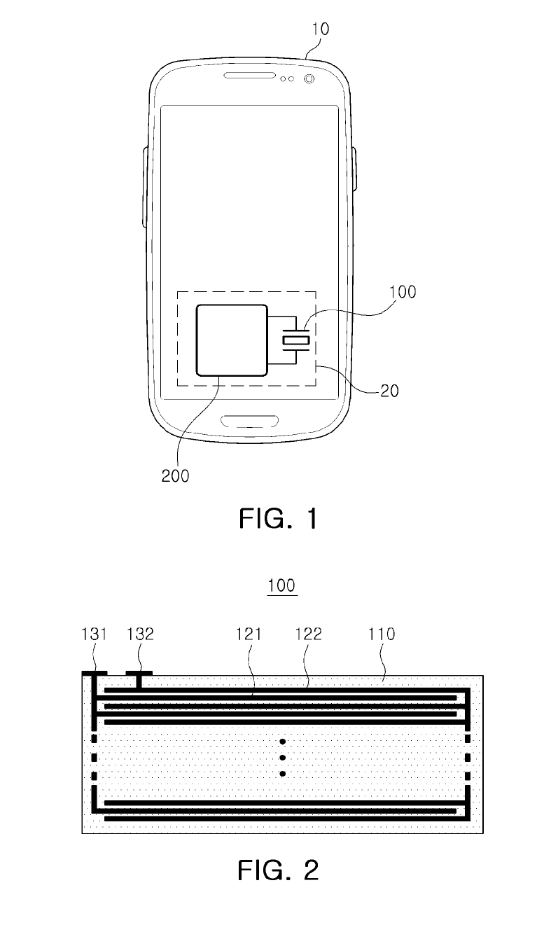

FIG. 1 is a diagram of an electronic device according to an exemplary embodiment in the present disclosure.

As illustrated in FIG. 1, an electronic device 10 may include a piezoelectric actuator 20.

Although FIG. 1 illustrates a smart phone as an example of the electronic device, it is merely exemplary and the electronic device may collectively refer to independently drivable computing apparatuses such as tablet PCs, or vehicle navigation devices.

The piezoelectric actuator 20 may provide vibrations or user feedback to the electronic device 10. For example, the piezoelectric actuator 20 may provide vibrations in response to user touch interactions.

The piezoelectric actuator 20 may include a multilayer piezoelectric element 100 and a piezoelectric driving apparatus 200.

The multilayer piezoelectric element 100 may include a plurality of stacked piezoelectric layers.

The piezoelectric driving apparatus 200 may generate an asymmetrical driving signal and may apply the asymmetrical driving signal to the piezoelectric element 100.

The piezoelectric driving apparatus 200 may provide a first differential signal having an absolute value of a positive peak value higher than an absolute value of a negative peak value to a positive electrode terminal of the multilayer piezoelectric element 100, and may provide a second differential signal having an absolute value of a positive peak value lower than an absolute value of a negative peak value to a negative electrode terminal of the multilayer piezoelectric element 100.

The multilayer piezoelectric element 100 and the piezoelectric driving apparatus 200 as mentioned above will be described hereinbelow in greater detail.

FIG. 2 is a cross-sectional view of a multilayer piezoelectric element according to an exemplary embodiment in the present disclosure.

As illustrated in FIG. 2, the multilayer piezoelectric element 100 according to the present exemplary embodiment may have a multilayer structure in which a plurality of piezoelectric layers 110 are stacked. Internal electrodes 121 and 122 may be formed in the plurality of piezoelectric layers 110 in an alternating manner. The internal electrodes 121 and 122 may include a positive internal electrode 121 and a negative internal electrode 122.

The positive internal electrode 121 and the negative internal electrode 122 may be disposed in the plurality of piezoelectric layers 110 in an alternating manner, and may be stacked together with the plurality of piezoelectric layers 110 to thereby form the multilayer piezoelectric element 100.

The plurality of piezoelectric layers 110 may be formed of a ceramic material, and may be manufactured in a planar ceramic sheet form using particulate ceramic powder particles. Such a plurality of planar ceramic sheets may be stacked to form the piezoelectric layers 110, and the piezoelectric layers 110 may have the multilayer structure, and may generate displacement in a lengthwise direction through a voltage applied thereto. Here, the voltage applied to the multilayer structure in which the piezoelectric layers 110 are stacked may be applied through the internal electrodes 121 and 122 formed in the piezoelectric layers 110.

The internal electrodes 121 and 122 may be formed of a metallic material having relatively high conductivity, and may be mainly formed of an Ag—Pd alloy. The internal electrodes 121 and 122 may form positive electrodes and negative electrodes in the multilayer structure in which the plurality of piezoelectric layers 110 are stacked, and may be alternately and iteratively stacked on the piezoelectric layers 110 to thereby form the multilayer piezoelectric element having polarity.

In addition, the internal electrodes 121 and 122 disposed between the piezoelectric layers 110 and having the same polarity may be electrically connected to one another while forming the positive electrode and the negative electrode in an alternating manner. The internal electrodes 121 and 122 having the positive and negative polarities may be electrically connected to a positive electrode terminal 131 and a negative electrode terminal 132, respectively, exposed to one surface of the multilayer structure through lead wires.

Therefore, the multilayer piezoelectric element 100 may have driving signals from the piezoelectric driving apparatus 200 applied thereto through the positive electrode terminal 131 and the negative electrode terminal 132.

Since the multilayer piezoelectric element 100 has a driving voltage level lower than that of a non-multilayer piezoelectric element, the multilayer piezoelectric element 100 may generate an output having a level equal to that output by the single multilayer piezoelectric element, while consuming a relatively small amount of power. Therefore, the use of the multilayer piezoelectric element 100 has been popularized in fields in which power management is important.

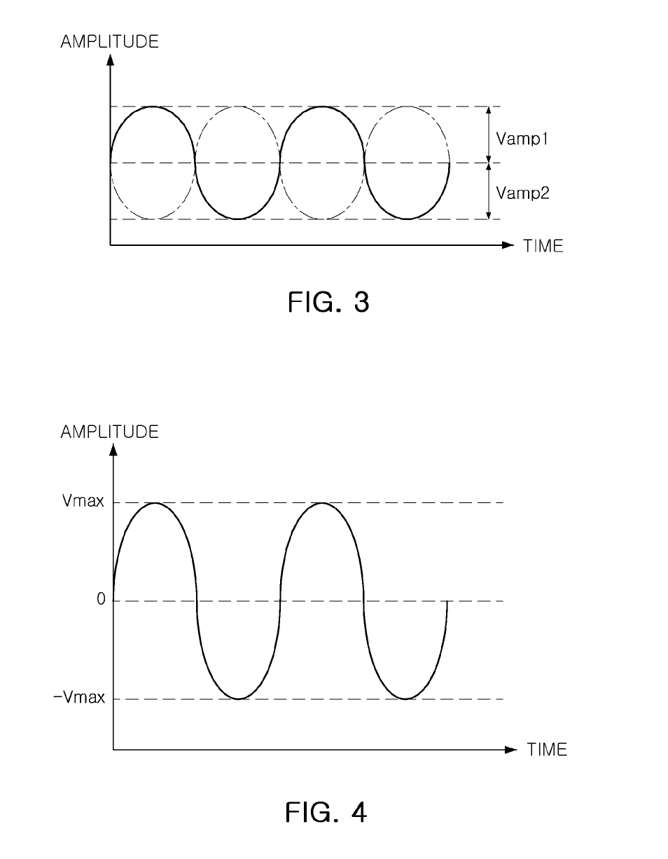

FIG. 3 is a graph illustrating an example of a pair of differential signals applied to both electrode terminals of the multilayer piezoelectric element, respectively, and FIG. 4 is a graph illustrating the differential signals of FIG. 3 as a single driving signal.

The graph of FIG. 3 illustrates an example of a pair of differential signals having phases opposite to one another. The pair of differential signals may be input to both of the electrode terminals of the multilayer piezoelectric element, respectively. For example, a signal denoted by a solid bold line may be input to a positive electrode terminal of the multilayer piezoelectric element and a signal denoted by a dashed line may be input to a negative electrode terminal of the multilayer piezoelectric element.

In the illustrated example, differential signals having symmetrical amplitudes are illustrated. That is, the differential signals in the illustrated example have a positive amplitude Vamp1 and a negative amplitude Vamp2 having the same level of amplitude.

FIG. 4 is a graph illustrating the differential signals of FIG. 3 as a single driving signal. The graph of FIG. 4 may be derived by subtracting a second signal applied to a negative electrode terminal of the multilayer piezoelectric element from a first signal applied to a positive electrode terminal of the multilayer piezoelectric element of FIG. 3.

The differential signals of FIG. 3 may be signals applied to both of the electrode terminals of the multilayer piezoelectric element, respectively, and the driving signal of FIG. 4 may be a signal illustrating the differential signals of FIG. 3 as a single signal. As described hereinbefore, it may be appreciated that the driving signal applied to the multilayer piezoelectric element illustrated in FIG. 4 may also have a symmetrical form.

As described hereinbefore with reference to FIGS. 3 and 4, a symmetrical driving signal may be used as an example of a signal for driving the multilayer piezoelectric element. However, in a case of using such a symmetrical driving signal, a level of the applied driving signal, that is, a voltage level thereof, may be limited.

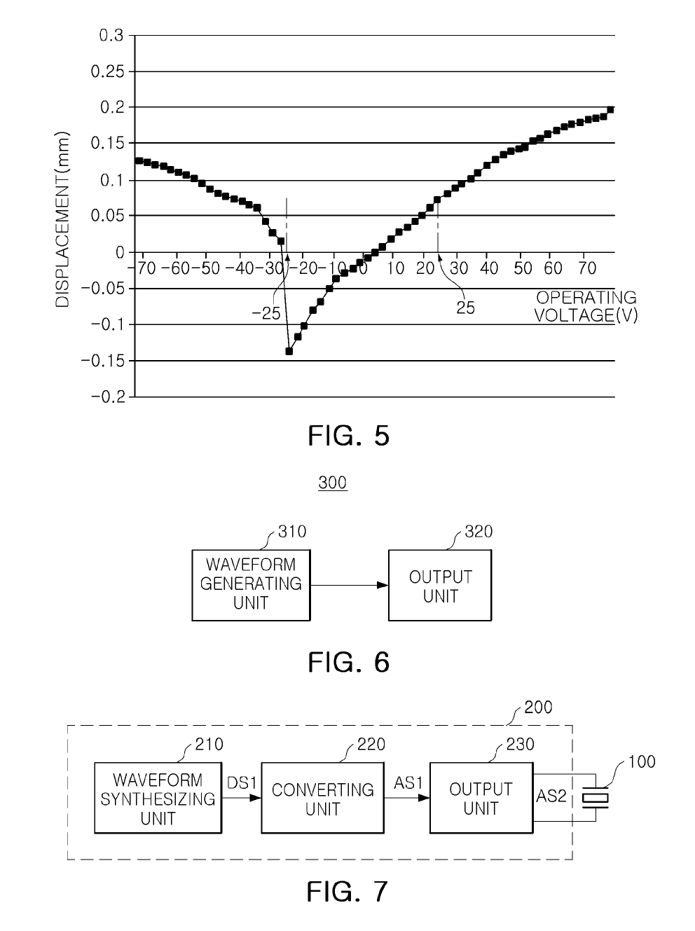

The reason is that characteristics of the multilayer piezoelectric element may be lost in a case in which a level of voltage applied in a reverse direction of polarization characteristics of the multilayer piezoelectric element is high. Descriptions pertaining thereto will be provided hereinbelow in greater detail with reference to FIG. 5.

In addition, as the number of stacked multilayer piezoelectric elements is increased, limitations for a voltage which may be applied to the multilayer piezoelectric element may also be increased.

FIG. 5 is a graph illustrating an example of displacement depending on a voltage applied to the multilayer piezoelectric element, and voltage limitations for the multilayer piezoelectric element will be described with reference to FIG. 5.

The example illustrated in FIG. 5 is the graph illustrating a driving voltage of and displacement in an example of the multilayer piezoelectric element having twelve piezoelectric layers. Dimensions denoted in the illustrated graph may be varied depending on a material, a thickness, and the like, of the piezoelectric layer.

As illustrated in the graph, it may be appreciated that an operational displacement of the multilayer piezoelectric element is increased in a positive region of the driving voltage as the level of the applied voltage is increased. For example, as the applied operating voltage is increased from 0V to 70V, it may be appreciated that the operational displacement of the multilayer piezoelectric element is proportionally increased. The reason is that the voltage is applied in a forward direction of the polarization characteristics of the multilayer piezoelectric element.

On the other hand, it may be appreciated that a reverse displacement occurs at a predetermined voltage level or less in a negative region of the driving voltage. That is, it may be appreciated that a negative operational displacement of the multilayer piezoelectric element is increased as an absolute value of the driving voltage is increased up to a predetermined threshold value of a negative operating voltage, that is, from 0V to −25V in the illustrated example, but the negative operational displacement may be rapidly changed to positive displacement in a case in which a negative voltage beyond the predetermined threshold value, that is, −25V in the illustrated example is applied.

Such a phenomenon may occur since the driving voltage having polarization characteristics opposite to the polarization characteristics of the multilayer piezoelectric element is strongly applied to the multilayer piezoelectric element so as to depolarize the multilayer piezoelectric element. Therefore, when such a depolarization phenomenon occurs, the multilayer piezoelectric element may lose characteristics thereof.

As a result, in a case in which a driving voltage is strongly applied to the multilayer piezoelectric element in a negative direction, the polarization characteristics of the piezoelectric layers of the multilayer piezoelectric element may be lost, and consequently, operational characteristics of the multilayer piezoelectric element may be lost.

Consequently, as the driving voltage of the multilayer piezoelectric element, it is necessary to use a driving voltage having a voltage level higher than the negative threshold value, that is, −25V in the example of FIG. 5.

Therefore, in a case in which a symmetrical driving signal is used, the driving voltage may need to be limited to a range of −25V to +25V. Consequently, in a case in which the symmetrical driving signal is used, a positive voltage threshold value corresponding to a negative voltage threshold value of the multilayer piezoelectric element may be required.

Since depolarization may easily occur due to the voltage applied in the reverse direction as the number of stacked multilayer piezoelectric elements is increased or a thickness of each layer is reduced, an available range of the driving voltage may be decreased.

Hereinafter, as an exemplary embodiment in the present disclosure, a waveform generating method and a piezoelectric driving method using an asymmetrical driving signal will be descried.

The waveform generating method may provide a relatively high level of output while satisfying the limitations of the driving voltage, that is, the negative threshold value of the driving voltage, of operational elements such as the multilayer piezoelectric element, or the like, as described hereinbefore, by applying the asymmetrical driving signal. That is, the piezoelectric driving method according to the exemplary embodiment may generate a relatively high level of output while satisfying the limitations of the driving voltage of the multilayer piezoelectric element using the asymmetrical driving signal in which amplitudes of first and second polarities are different from one another.

For example, in a case of the example described hereinbefore in FIG. 5, when it is assumed that the negative voltage threshold value at which characteristics of the multilayer piezoelectric element are lost is −25V, a maximum negative value of −25V of the driving signal and a maximum positive value of 35V of the driving signal may be used to be asymmetrical with one another by using the positive value of the driving signal having a value higher than 25V, for example, 35V.

That is, an absolute value of the positive voltage may be higher than an absolute value of the negative voltage. In this case, since a range of the positive operating voltage may be increased while satisfying the negative voltage threshold value such that the characteristics of the multilayer piezoelectric element are not lost, the multilayer piezoelectric element may generate a relatively high level of output.

As such, since the case of using the asymmetrical driving signal has a level of a peak-to-peak voltage which is higher than that of a case of using the symmetrical driving signal, a relatively high level of output may be generated when the asymmetrical driving signal is used.

According to the exemplary embodiment, the multilayer piezoelectric element may be formed by stacking eight to twenty four piezoelectric layers, each of which has a thickness of 10 micrometers (μm) or more to 100 μm or less.

The following Table 1 illustrates the number of piezoelectric layers of the multilayer piezoelectric element and amplitudes of the driving signals depending on the number of piezoelectric layers. In Table 1, the thickness of the piezoelectric layer may be within a range of 10 μm to 100 μm.

TABLE 1

| Number of Piezoelectric | Minimum Negative | Maximum Positive |
|---|---|---|
| Layers | Amplitude | Amplitude |
| 12 | −25 | 35 |
| 24 | −12.5 | 17.5 |

In an example illustrated in Table 1, the multilayer piezoelectric element may be formed by stacking twelve piezoelectric layers, and the amplitude of the driving signal input to the multilayer piezoelectric element may have a level between a minimum level of −25V and a maximum level of 35V. In another example, the multilayer piezoelectric element may be formed by stacking twenty four piezoelectric layers and the amplitude of the driving signal input to the multilayer piezoelectric element may have a level between a minimum level of −12.5V and a maximum level of 17.5V.

Referring to Table 1, it may be appreciated that the range of the driving signal applied to the multilayer piezoelectric element is changed depending on the number of piezoelectric layers. In general, it may be appreciated that the negative threshold value of the driving signal, that is, the negative threshold value at which the characteristics of the multilayer piezoelectric element are lost, is increased as the number of piezoelectric layers is increased or the thickness of the piezoelectric layer is reduced.

As described hereinbefore, it may be appreciated from the exemplary embodiment that the driving signal is applied by allowing the negative voltage range and the positive voltage range to be asymmetrical with one another. Hereinafter, various exemplary embodiments of a signal generating apparatus, a piezoelectric driving apparatus, and a circuit using such an asymmetrical signal will be described in greater detail with reference to FIGS. 6 through 15.

FIG. 6 is a block diagram illustrating an example of a signal generating apparatus according to an exemplary embodiment in the present disclosure. A signal generating apparatus 300 according to the present exemplary embodiment relates to a signal generating apparatus for outputting an asymmetrical signal, and a purpose and a technological application thereof are not limited to a specific field.

Referring to FIG. 6, the signal generating apparatus 300 may include a waveform generating unit 310 and an output unit 320.

The waveform generating unit 310 may output an alternating current (AC) signal.

The output unit 320 may shift the AC signal output from the waveform generating unit 310, and may generate an asymmetrical driving signal.

According to the exemplary embodiment, the asymmetrical driving signal may be an asymmetrical waveform in which amplitudes of first and second polarities are different from one another.

According to the exemplary embodiment, the output unit 320 may add a direct current (DC) voltage to the AC signal to shift the AC signal.

Hereinafter, a piezoelectric driving apparatus will be described as an example of the signal generating apparatus. Since various exemplary embodiments of the piezoelectric driving apparatus may be applied to the signal generating apparatus, the signal generating apparatus and the piezoelectric driving apparatus in the exemplary embodiment may have technical characteristics and configurations corresponding to one another without providing additional descriptions.

FIG. 7 is a block diagram illustrating an example of a piezoelectric driving apparatus according to an exemplary embodiment in the present disclosure.

A piezoelectric driving apparatus 200 may apply a predetermined driving signal to the multilayer piezoelectric element 100 to drive the multilayer piezoelectric element 100.

According to the exemplary embodiment, the piezoelectric driving apparatus 200 may provide a first differential signal shifted in a positive direction to the positive electrode terminal of the multilayer piezoelectric element 100, and may provide a second differential signal shifted in a negative direction to the negative electrode terminal of the multilayer piezoelectric element 100.

Hereinafter, a pair of signals applied to both of the electrode terminals of the multilayer piezoelectric element 100, respectively, are referred to as differential signals, and a signal applied to the multilayer piezoelectric element 100 in the form of a pair of differential signals, that is, a pair of differential signals having the form of a single signal, is referred to as a driving signal.

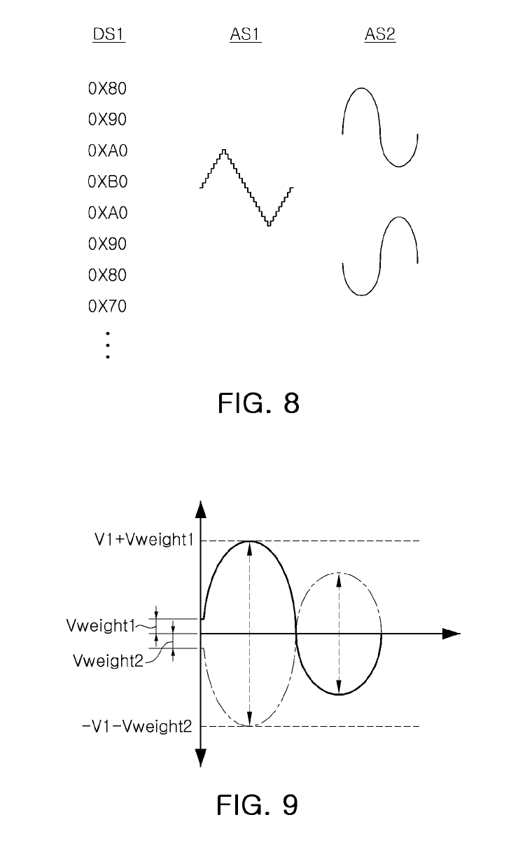

FIG. 8 illustrates signals respectively output from components of the piezoelectric driving apparatus of FIG. 7.

A waveform synthesizing unit 210 may output a digital value DS1.

A converting unit 220 may convert the input digital value DS1 into an analog signal AS1. The converting unit 220 may convert the digital value DS1 into the analog signal AS1 in each of a plurality of predetermined periods of time, and may output an analog signal in a form of a stepped waveform as illustrated in FIG. 8.

An output unit 230 may output an input analog signal. The output unit 230 may generate an asymmetrical driving signal using the input analog signal.

For example, the output unit 230 may include a differential amplifier. The output unit 230 may generate two sine waves, that is, differential signals AS2, using the analog signal AS1, and may provide the generated differential signals AS2 to both of the electrode terminals of the piezoelectric element 100, respectively. The output unit 230 may shift the differential signals, and may generate an asymmetrical driving signal.

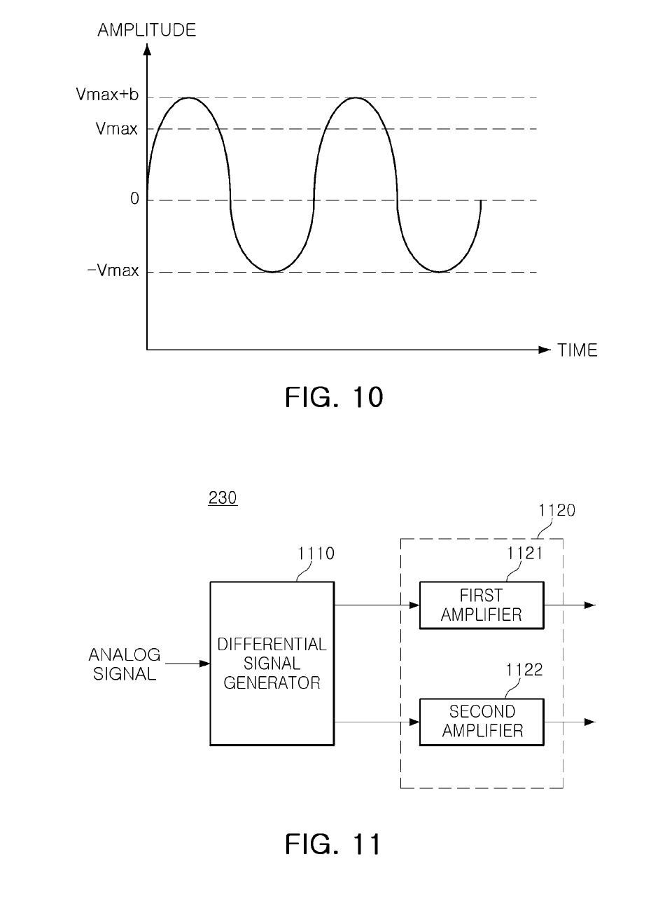

Such an asymmetrical signal will be described hereinbelow in greater detail with reference to FIGS. 9 and 10.

FIG. 9 illustrates an example of the differential signals provided from the piezoelectric driving apparatus of FIG. 7, and FIG. 10 illustrates an example of the driving signal obtained from the differential signals of FIG. 9.

FIG. 9 illustrates the differential signals input to both of the electrode terminals of the piezoelectric element 100, respectively. The pair of differential signals may have phases opposite to one another.

The differential signals may have a maximum amplitude of first polarity and a maximum amplitude of second polarity different from one another. It may be appreciated from the illustrated example that a first differential signal denoted by a solid bold line has a maximum positive amplitude greater than a maximum negative amplitude, and a second differential signal denoted by a dashed line has a maximum negative amplitude greater than a maximum positive amplitude. That is, it may be appreciated that the first differential signal is shifted in a positive direction by a level of a first DC voltage Vweight1 and the second differential signal is shifted in a negative direction by a level of a second DC voltage Vweight2.

The first differential signal may be applied to the positive electrode terminal of the piezoelectric element 100 and the second differential signal denoted by the dashed line may be applied to the negative electrode terminal of the piezoelectric element 100.

The pair of differential signals may have DC voltages added thereto having levels equal to or different from one another. That is, although the illustrated example illustrates a case in which the level of the first DC voltage Vweight1 added to the first differential signal is equal to the level of the second DC voltage Vweight2 added to the second differential signal, it is merely illustrative, and the two DC voltages may have levels different from one another according to exemplary embodiments.

According to the exemplary embodiment, the DC voltage may have a preset voltage level. For example, the DC voltage may have a predetermined voltage level.

According to exemplary embodiments, the DC voltage may be a predetermined weighted voltage multiplied by an output signal. For example, the DC voltage may be a constant voltage multiplied by each of amplitude of the differential signals generated by the output unit 230.

FIG. 10 is a graph illustrating the differential signals of FIG. 9 as a single driving signal. FIG. 10 may be derived by subtracting one differential signal from the other differential signal of FIG. 9. As illustrated in FIG. 10, it may be appreciated that the driving signal applied to the multilayer piezoelectric element is an asymmetrical signal having a positive amplitude greater than a negative amplitude.

As described hereinbefore with reference to FIGS. 9 and 10, the signal provided by the piezoelectric driving apparatus 200 may be the asymmetrical signal. By applying the asymmetrical signal to the multilayer piezoelectric element 100, a relatively high level of driving voltage may be provided while satisfying the negative threshold value of the multilayer piezoelectric element 100, such that a relatively high level of output may be obtained.

Again, the respective components of the piezoelectric driving apparatus 200 will be described in greater detail with reference to FIG. 7.

The piezoelectric driving apparatus 200 may include a waveform synthesizing unit 210, a converting unit 220, and an output unit 230.

According to exemplary embodiments, the components of the piezoelectric driving apparatus 200 may each be provided as a discrete circuit or a discreet integrated circuit, or may be incorporated into a single circuit or a single integrated circuit.

The waveform synthesizing unit 210 may output a predetermined digital value for generating the driving signal. The digital value may be converted into the analog signal by the converting unit 220, and the analog signal may change to the differential signal through the output unit 230 and may be applied to the multilayer piezoelectric element 100.

According to the exemplary embodiment, the waveform synthesizing unit 210 may output the digital value based on an external input. The external input, a signal input from the outside of the piezoelectric driving apparatus, may be provided from, for example, a main central processing unit (CPU), a control integrated circuit (IC), or a micro controller unit (MCU) of a mobile device, or the like, including the piezoelectric driving apparatus.

According to the exemplary embodiment, the waveform synthesizing unit 210 may output the digital value using a lookup table. For example, the waveform synthesizing unit 210 may select the digital value to be output from the lookup table in which a plurality of digital values are stored using the external input.

According to exemplary embodiments, the waveform synthesizing unit 210 may output the digital value using a function of outputting a predetermined digital value based on the external input. For example, the function may apply a preset equation to the external input to output the digital value.

The converting unit 220 may convert the digital value to an analog signal. According to the exemplary, the converting unit 220 may be a digital-to-analog converter.

The output unit 230 may generate a pair of output waveforms using the analog signal, and may shift the pair of output waveforms to output the pair of shifted output waveforms.

According to the exemplary embodiment, the output unit 230 may add a DC voltage to the pair of output waveforms to shift the pair of output waveforms by a level of the added DC voltage.

According to the exemplary embodiment, the output unit 230 may add a predetermined DC voltage to the analog signal to generate the asymmetrical driving signal. That is, the output unit 230 may add the predetermined DC voltage to perform shifting. It may be appreciated from the example of FIG. 9 that a solid bold line illustrates a case in which the positive DC voltage Vweight1 is added to the analog signal, and a dashed line illustrates a case in which the negative DC voltage Vweight2 is added to the analog signal. Here, the positive DC voltage may have an absolute value corresponding to that of the negative DC voltage.

According to the exemplary embodiment, the output unit 230 may generate the pair of differential signals using the analog signal converted from the converting unit 220, and may apply the pair of differential signals to both of the electrode terminals of the multilayer piezoelectric element 100, respectively.

According to the exemplary embodiment, the output unit 230 may shift the differential signal input to the positive electrode terminal of the multilayer piezoelectric element 100, in a positive voltage direction, and may shift the differential signal input to the negative electrode terminal of the multilayer piezoelectric element 100, in a negative voltage direction.

It may be appreciated from the example of FIG. 9 that the waveform denoted by the solid bold line is shifted in the positive voltage direction by the level of the DC voltage Vweight1, and the waveform denoted by the dashed line is shifted in the negative direction by the level of the DC voltage Vweight2. This is to apply a relatively high level of voltage in a polarization direction of the multilayer piezoelectric element 100, and to allow a level of the DC voltage input to the multilayer piezoelectric element 100 not to be deviated from a limitation value of the negative voltage in a direction opposite to the polarization direction.

FIG. 11 is a block diagram illustrating an example of the output unit of FIG. 7.

Referring to FIG. 11, the output unit 230 may include a differential signal generator 1110 and an amplifier 1120.

The differential signal generator 1110 may receive an analog signal, and may output a pair of differential signals. According to the exemplary embodiment, the differential signal generator 1110 may generate a phase signal opposite to the received analog signal, and may output the generated opposite phase signal and the received analog signal.

The amplifier 1120 may shift the received differential signals to convert the differential signals into asymmetrical signals. The amplifier 1120 may amplify and output the shifted differential signals.

According to the exemplary embodiment, the amplifier 1120 may add DC voltages to the differential signals to convert the differential signals into the asymmetrical signals.

Since the amplifier 1120 performs a shift function, the amplifier 1120 may be provided by another component performing such a shift function. According to the exemplary embodiment, a level-shifter, or the like may be used in lieu of the amplifier 1120.

According to the exemplary embodiment, the amplifier 1120 may use the DC voltage as a reference voltage to shift the differential signals.

According to the exemplary embodiment, the amplifier 1120 may include a first amplifier 1121 and a second amplifier 1122. The first amplifier 1121 and the second amplifier 1122 may add the DC voltages to the received differential signals, respectively, and may output the shifted differential signals.

According to the exemplary embodiment, the first amplifier 1121 may add a positive DC voltage to a first differential signal to shift the first differential signal such that a positive peak value thereof is increased, and the second amplifier 1122 may add a negative DC voltage to a second differential signal to shift the second differential signal such that a negative peak value thereof is decreased.

According to the exemplary embodiment, the first amplifier 1121 and the second amplifier 1122 may add the DC voltages having polarities opposite to one another, respectively. For example, the first amplifier 1121 may add the positive DC voltage to the received differential signal, and the second amplifier 1122 may add the negative DC voltage to the received differential signal.

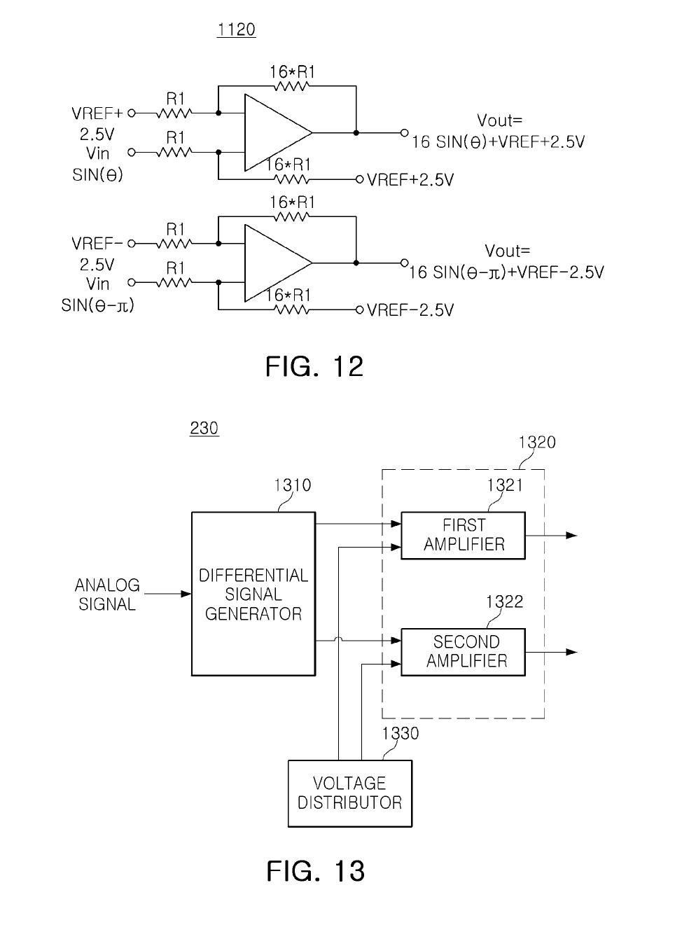

FIG. 12 is a circuit diagram illustrating an example of the amplifier of FIG. 11. The example of FIG. 12 relates to an example in which a gain ratio of each signal is 16, and DC voltages of 2.5V may be applied to reference terminals.

As illustrated in FIG. 12, it may be appreciated that the DC voltage of +2.5V or −2.5V is applied to a reference terminal of the amplifier. That is, the DC voltage may be applied to the reference terminal, such that a reference value of the differential signal may rise or drop by the DC voltage of +2.5V or −2.5V. Consequently, an output of the amplifier may be shifted in a positive or negative direction.

FIG. 13 is a block diagram illustrating another example of the output unit of FIG. 7.

Referring to FIG. 13, the output unit 230 may include a differential signal generator 1310, an amplifier 1320, and a voltage distributor 1330.

Since the differential signal generator 1310 and the amplifier 1320 correspond to those described hereinbefore with reference to FIGS. 11 and 12, repeated descriptions will be omitted for conciseness.

The voltage distributor 1330 may provide a DC voltage to the amplifier 1320. For example, the DC voltage may have a predetermined voltage level.

The voltage distributor 1330 may provide the DC voltages to reference terminals of the amplifier 1320.

According to the exemplary embodiment, the voltage distributor 1330 may be connected to the reference terminals of first and second amplifiers 1321 and 1322, and may provide the DC voltages to the first and second amplifiers 1321 and 1322, respectively.

According to the exemplary embodiment, the voltage distributor 1330 may generate, in a dissimilar manner, the DC voltages provided to the first and second amplifiers 1321 and 1322, respectively.

According to the exemplary embodiment, the voltage distributor 1330 may adjust a level of the DC voltage. For example, the voltage distributor 1330 may include a voltage adjusting circuit and a distributing circuit, and may adjust the distributing circuit to adjust the level of the DC voltage to be output.

According to the exemplary embodiment, the voltage distributor 1330 may provide or block the DC voltages to the first and second amplifiers 1321 and 1322 depending on a mode input signal input externally. That is, the voltage distributor 1330 may determine the DC voltage level to be zero.

For example, the piezoelectric driving apparatus 200 may selectively use an asymmetrical waveform and a symmetrical waveform. In a case of using the symmetrical waveform, that is, in a case in which the DC voltage is not added, the voltage distributor 1330 may set the DC voltage level to be zero.

Hereinbefore, various examples of the piezoelectric driving apparatus adding the asymmetrical waveform have been described with reference to FIGS. 7 through 13.

Although the aforementioned descriptions are provided based on a case in which the DC voltages are added to both of the pair of differential signals, respectively, asymmetrical driving may be performed by adding the DC voltage to only one of the pair of differential signals according to exemplary embodiments.

In addition, although the aforementioned descriptions are provided based on the exemplary embodiment in which the differential signals are generated and the DC voltages are then added thereto, the differential signals may be generated subsequently to add the DC voltages to an analog signal according to exemplary embodiments.

The piezoelectric driving apparatus described hereinbefore may stably generate an asymmetrical signal using a single voltage. Therefore, the piezoelectric driving apparatus may stably generate the asymmetrical driving signal even in a circumstance in which a power voltage is limited such as in a mobile terminal, for example, a cellular phone, a tablet PC, or a vehicle navigation device, and may provide a relatively high level of output using the asymmetrical driving signal.

Hereinbefore, various exemplary embodiments of the piezoelectric driving apparatus have been described with reference to FIGS. 6 through 13, and signal generating circuits may be provided according to the exemplary embodiments of the piezoelectric driving apparatus described hereinbefore.

For example, the signal generating circuit including a differential signal generating circuit and a comparing circuit may be provided. Alternatively, the signal generating circuit including an outputting circuit including the differential signal generating circuit and the comparing circuit, and a digital-to-analog converting circuit may be provided.

That is, the signal generating circuit corresponding to the descriptions provided with reference to FIGS. 6 through 13 may be disclosed according to the exemplary embodiments in the present disclosure. However, since the description of the signal generating circuit corresponds to those described hereinbefore, the repeated descriptions will be omitted for conciseness.

The signal generating circuit may include the differential signal generating circuit receiving an analog signal to generate a pair of differential signals, and the comparing circuit shifting the pair of differential signals.

According to the exemplary embodiment, the comparing circuit may include a first amplifier adding a positive DC voltage to a first differential signal, and a second amplifier adding a negative DC voltage to a second differential signal.

According to the exemplary embodiment, the signal generating circuit may further include a voltage distributing circuit connected to reference terminals of first and second amplifiers so as to provide the DC voltages to the first and second amplifiers, respectively.

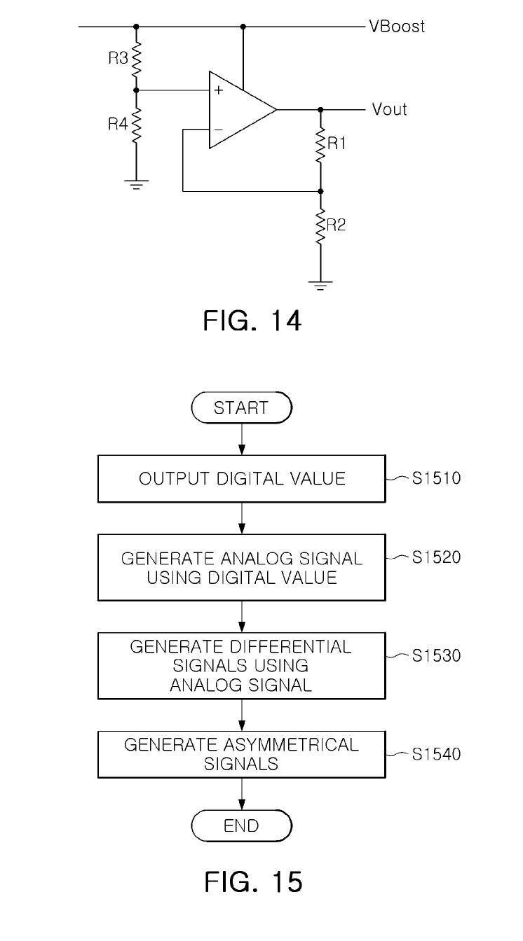

FIG. 14 is a circuit diagram illustrating an example of the voltage distributor of FIG. 13.

An output of the voltage distributor illustrated in FIG. 14 may be represented by Equation 1, in which REFERENCE VOLTAGE is a voltage of a node between R3 and R4 and A_{OL} (A_{OL}>>1) is the gain of the amplifier.

$$Vboost \frac{{R}_{4}}{{R}_{3} + {R}_{4}} = REFERENCE VOLTAGE \\ {R}_{3} \text{:} {R}_{4} = 9 \text{:} 1 \\ {V}_{OUT} = \frac{{R}_{1} + {R}_{2}}{{R}_{2}} \frac{{A}_{OL}}{1 + {A}_{OL}} 0.1 \cdot Vboost ≅ \frac{{R}_{1} + {R}_{2}}{{R}_{2}} 0.1 \cdot Vboost \qquad Equation 1$$

As can be seen from Equation 1, the voltage distributor may adjust an output as a resistance ratio, that is, a DC voltage. According to the exemplary embodiment, the voltage distributor may adjust a level of the DC voltage using a variable resistor, or the like, in addition to providing a fixed DC voltage.

FIG. 15 is a flowchart describing an example of a signal generating method. Since a signal generating method to be described hereinbelow may be performed by the piezoelectric driving apparatus described hereinbefore with reference to FIGS. 1 through 14, descriptions identical to or equivalent to the above-mentioned descriptions will be omitted.

Referring to FIG. 15, in operation S1510, a waveform generating apparatus may select a digital value.

The waveform generating apparatus may select the digital value in various manners. For example, the waveform generating apparatus may select the digital value using a preset lookup table or using a predetermined function. Alternatively, the waveform generating apparatus may select the digital value using a digital signal processing scheme, or the like.

In operation S1520, the waveform generating apparatus may generate an analog signal using the digital value.

In operation S1530, the waveform generating apparatus may generate differential signals using the analog signal. In operation S1540, the waveform generating apparatus may shift the differential signals to generate asymmetrical signals. According to the exemplary embodiment, the waveform generating apparatus may add DC voltages having different polarities to first and second analog signals, respectively, so as to generate an asymmetrical driving signal.

According to the exemplary embodiment of S1530, the waveform generating apparatus may convert the digital value to generate the first analog signal, and may invert a phase of the first analog signal to generate the second analog signal.

According to the exemplary embodiment of S1530, the waveform generating apparatus may add a positive DC voltage to the first analog signal. In addition, the waveform generating apparatus may add a negative DC voltage to the second analog signal.

According to the exemplary embodiment of S1530, the waveform generating apparatus may apply a first shifted analog signal to a positive electrode terminal of the multilayer piezoelectric element, and may apply a second shifted analog signal to a negative electrode terminal of the multilayer piezoelectric element.

As set forth above, according to exemplary embodiments in the present disclosure, characteristics of the multilayer piezoelectric element may be protected, and a relatively high level of output may be provided simultaneously.

While exemplary embodiments have been shown and described above, it will be apparent to those skilled in the art that modifications and variations could be made without departing from the scope of the present invention as defined by the appended claims.

What is claimed is:

1. A signal generating apparatus, comprising:
a waveform generating unit outputting an alternating current (AC) signal; and
an output unit generating an asymmetrical driving signal by shifting the AC signal.

2. The signal generating apparatus of claim 1, wherein the asymmetrical driving signal has an asymmetrical waveform in which amplitudes of first and second polarities of the asymmetrical driving signal are different from one another.

3. The signal generating apparatus of claim 1, wherein the output unit adds a direct current (DC) voltage to the AC signal to shift the AC signal.

4. A signal generating apparatus, comprising:
a waveform synthesizing unit outputting a digital value;
a digital-to-analog converting unit converting the digital value received from the waveform synthesizing unit to an analog signal; and
an output unit generating a pair of waveforms using the analog signal, shifting the pair of waveforms, and outputting the pair of shifted waveforms.

5. The signal generating apparatus of claim 4, wherein the pair of shifted waveforms output from the output unit are asymmetrical waveforms in which amplitudes of first and second polarities of the output waveform are different from one another.

6. The signal generating apparatus of claim 4, wherein the output unit adds DC voltages to the pair of waveforms, respectively, to shift the pair of waveforms by a level of the DC voltages.

7. The signal generating apparatus of claim 4, wherein the output unit provides a waveform shifted in a positive direction of the pair of waveforms to a positive electrode terminal of a multilayer piezoelectric element.

8. The signal generating apparatus of claim 4, wherein the output unit includes:
a differential signal generator generating a pair of differential signals using the analog signal; and
first and second amplifiers adding DC voltages to the pair of differential signals, respectively.

9. The signal generating apparatus of claim 8, wherein the first amplifier adds a positive DC voltage to a first differential signal to shift the first differential signal such that a positive peak value of the first differential signal is increased, and
the second amplifier adds a negative DC voltage to a second differential signal to shift the second differential signal such that a negative peak value of the second differential signal is decreased.

10. The signal generating apparatus of claim 9, wherein the positive DC voltage has an absolute value equal to that of the negative DC voltage.

11. A signal generating apparatus, comprising:
a waveform synthesizing unit outputting a digital value;
a digital-to-analog converting unit converting the digital value to an analog signal; and
an output unit generating an asymmetrical driving signal by adding a direct current (DC) voltage to the analog signal.

12. The signal generating apparatus of claim 11, wherein the output unit generates a pair of differential signals using the analog signal, and adds different DC voltages to the pair of differential signals, respectively.

13. The signal generating apparatus of claim 12, wherein the output unit adds a positive DC voltage to a first differential signal input to a positive electrode terminal of a multilayer piezoelectric element, and adds a negative DC voltage to a second differential signal input to a negative electrode terminal of the multilayer piezoelectric element.

14. The signal generating apparatus of claim 11, wherein the output unit includes:
a differential signal generator generating a pair of differential signals using the analog signal; and
first and second amplifiers adding DC voltages to the pair of differential signals, respectively.

15. The signal generating apparatus of claim 14, wherein the first amplifier has a positive DC voltage input thereto as a reference voltage, and
the second amplifier has a negative DC voltage input thereto as a reference voltage.

16. The signal generating apparatus of claim 15, wherein the output unit further includes a voltage distributor connected to reference terminals of the first and second amplifiers so as to provide the positive DC voltage and the negative DC voltage to the first and second amplifiers, respectively.

17. The signal generating apparatus of claim 16, wherein the voltage distributor provides or blocks the positive DC voltage and the negative DC voltage to the first and second amplifiers, depending on a mode input signal input externally to the voltage distributor.

18. A piezoelectric driving apparatus driving a multilayer piezoelectric element in which a plurality of piezoelectric layers are stacked, characterized in that the piezoelectric driving apparatus provides a first differential signal having an absolute value of a positive peak value higher than an absolute value of a negative peak value to a positive electrode terminal of the multilayer piezoelectric element, and provides a second differential signal having an absolute value of a positive peak value lower than an absolute value of a negative peak value to a negative electrode terminal of the multilayer piezoelectric element.

19. The piezoelectric driving apparatus of claim 18, comprising:
a waveform synthesizing unit outputting a digital value;
a digital-to-analog converting unit converting the digital value to an analog signal; and
an output unit generating the first and second differential signals using the analog signal, and adding a positive direct current (DC) voltage and a negative DC voltage to the first and second differential signals, respectively.

20. A signal generating circuit, comprising:
a differential signal generating circuit receiving an analog signal to generate a pair of differential signals; and
a comparing circuit shifting the pair of differential signals.

21. The signal generating circuit of claim 20, wherein the comparing circuit includes:
a first amplifier adding a positive DC voltage to a first differential signal; and
a second amplifier adding a negative DC voltage to a second differential signal.

22. The signal generating circuit of claim 21, further comprising a voltage distributing circuit connected to reference terminals of the first and second amplifiers so as to provide the DC voltages to the first and second amplifiers, respectively.

23. An electronic device using a piezoelectric actuator, wherein the piezoelectric actuator comprises:
a multilayer piezoelectric element including a plurality of stacked piezoelectric layers; and
a piezoelectric driving apparatus generating an asymmetrical driving signal, and applying the asymmetrical driving signal to the multilayer piezoelectric element.

24. The electronic device of claim 23, wherein the piezoelectric driving apparatus includes:
a waveform synthesizing unit outputting a digital value;
a digital-to-analog converting unit converting the digital value to an analog signal; and
an output unit generating a pair of waveforms using the analog signal, shifting the pair of waveforms, and outputting the pair of shifted waveforms.

25. A signal generating method, comprising steps of:
selecting a digital value from a lookup table;
generating first and second analog signals using the digital value; and
generating an asymmetrical driving signal by shifting the first and second analog signals.

26. The signal generating method of claim 25, wherein the step of generating the first and second analog signals includes:
converting the digital value to generate a first analog signal; and
inverting a phase of the first analog signal to generate the second analog signal.

27. The signal generating method of claim 25, wherein the step of generating the asymmetrical driving signal includes:
adding a positive direct current (DC) voltage to the first analog signal; and
adding a negative DC voltage to the second analog signal.

28. The signal generating method of claim 27, wherein the step of generating the asymmetrical driving signal further includes:
applying the first analog signal to a positive electrode terminal of a multilayer piezoelectric element; and
applying the second analog signal to a negative electrode terminal of the multilayer piezoelectric element.
